(19) United States
(12) Patent Application Publication
(10) Pub. No.: US 2012/0286398 A1
(43) Pub. Date: Nov. 15, 2012

(54) SEMICONDUCTOR CHIP MODULE AND PLANAR STACK PACKAGE HAVING THE SAME

(75) Inventor: Seung Yeop LEE, Seoul (KR)

(73) Assignee: HYNIX SEMICONDUCTOR INC., Icheon-si (JP)

(21) Appl. No.: 13/334,461

(22) Filed: Dec. 22, 2011

(30) Foreign Application Priority Data
May 11, 2011 (KR) 10-2011-0044097

(51) Int. Cl. H01L 23/544

(52) U.S. Cl. 257/620; 257/737; 257/E23.179

(57) ABSTRACT

A semiconductor chip module includes a chip unit including at least two semiconductor chips disposed with a scribe lane interposed therebetween and each of which has a first surface on which bonding pads are disposed and a second surface that faces away from the first surface. Redistribution lines formed on the first surface of each semiconductor chip have first ends, which are connected with the bonding pads of each semiconductor chip, and second ends that extend to and are disposed on the scribe lane. Through electrodes formed to pass through the scribe lane are electrically connected with the second ends of the redistribution lines.

### CROSS-REFERENCE TO RELATED APPLICATIONS

The present application claims priority to Korean patent application number 10-2011-0044097 filed on May 11, 2011, which is incorporated herein by reference in its entirety.

### BACKGROUND OF THE INVENTION

The present invention relates to a semiconductor package, and more particularly, to a semiconductor chip module and a planar stack package having the same, while securing the processability of a package manufacturing process and the reliability of a package.

A semiconductor package has been developed to decrease its size and to improve its electrical characteristics. A typical example of such a semiconductor package includes a ball grid array (BGA) package. The BGA package has a structure in which a semiconductor chip is disposed on the upper surface of a substrate, the upper surface of the substrate including the semiconductor chip is then sealed, and a plurality of solder balls are attached as external connection terminals to the lower surface of the substrate. The substrate and the semiconductor chip are electrically connected with each other by bonding wires or bumps.

In the BGA package, since the overall size thereof is similar to the size of a chip, a mounting area may be minimized. Also, because electrical connections with an external circuit are formed by the solder balls, electrical characteristics may be enhanced by reducing electrical signal transfer paths.

Recently, there has been increasing demand for larger semiconductor products. In this regard, since limitations exist in increasing the capacity of a semiconductor chip itself, a stack package has been developed such that a required capacity can be achieved by vertically stacking at least two semiconductor chips in one package.

However, although the size of a memory chip shrinks, it is difficult to decrease the size of a package mounted with the memory chip due to limitations in ball pitch. Hence, in the case where a semiconductor chip with a decreased size is mounted in a package, it is difficult to achieve target processability and reliability.

### BRIEF SUMMARY OF THE INVENTION

An embodiment of the present invention is directed to a semiconductor chip module that can secure the processability of a package manufacturing process and the reliability of a package.

Also, an embodiment of the present invention is directed to a planar stack package having a semiconductor chip module, which can secure processability and reliability.

In one embodiment of the present invention, a semiconductor chip module includes a chip unit including at least two semiconductor chips disposed with a scribe lane in between adjacent semiconductor chips, and each of which has a first surface on which bonding pads are disposed and a second surface that faces away from the first surface. Redistribution lines, formed on the first surface of each semiconductor chip, have first ends connected with the bonding pads of each semiconductor chip and second ends that extend to and are disposed on the scribe lane. Through electrodes formed to pass through the scribe lane are electrically connected with the second ends of the redistribution lines.

The chip unit may have a structure in which at least two semiconductor chips are arranged with the scribe lane in between in a direction perpendicular to a direction along which the bonding pads are disposed.

The chip unit may have a structure in which at least two semiconductor chips are arranged with the scribe lane interposed therebetween in a direction perpendicular to a direction along which the bonding pads are disposed, and at least two rows of these semiconductor chips are arranged with the scribe lane interposed therebetween in the direction along which the bonding pads are disposed.

The semiconductor chips may be arranged in a 2×2 matrix.

The through electrodes may be formed to pass through the second ends of the redistribution lines and the scribe lane.

The semiconductor chip module may further include: bumps formed on ends of the through electrodes disposed on the second surface of each semiconductor chip.

In another embodiment of the present invention, a planar stack package includes: a semiconductor chip module including a chip unit including at least two semiconductor chips with a scribe lane interposed therebetween, and each semiconductor chip has a first surface on which bonding pads are disposed and a second surface that faces away from the first surface. Redistribution lines formed on the first surface of each semiconductor chip have first ends connected with the bonding pads of each semiconductor chip and second ends that extend to and are disposed on the scribe lane. Through electrodes formed to pass through the scribe lane are electrically connected with the second ends of the redistribution lines. A substrate having a first substrate surface on which the semiconductor chip module is placed and a plurality of bond fingers are disposed, and a second substrate surface that faces away from the first substrate surface and on which a plurality of ball lands are disposed. Connection members may electrically connect the bonding pads of the semiconductor chips with the bond fingers of the substrate.

The chip unit may have a structure in which the scribe lane is in a direction perpendicular to a direction along which the bonding pads are disposed.

The chip unit may have a structure in which at least two semiconductor chips are arranged with the scribe lane interposed therebetween in a direction perpendicular to a direction along which the bonding pads are disposed, and at least two rows of these semiconductor chips are arranged with the scribe lane interposed therebetween in the direction along which the bonding pads are disposed.

The semiconductor chips may be arranged in a 2×2 matrix.

In the semiconductor chip module, the bonding pads of each semiconductor chip may include first bonding pads disposed adjacent to one edge of the first surface and connected with the first ends of the redistribution lines and second bonding pads disposed adjacent to another edge of the first surface opposite to the one edge. The bond fingers of the substrate may include first bond fingers disposed on a center portion of the first substrate surface and second bond fingers disposed on portions of the first substrate surface outside the semiconductor chip module and connected with the second bonding pads of each semiconductor chip by the connection members.

The semiconductor chip module may further include bumps formed to connect the first bonding pads of each semiconductor chip with the first bond fingers of the substrate.

The semiconductor chip module may be placed over the first substrate surface of the substrate such that the second surface of each semiconductor chip faces the first substrate surface of the substrate, and the bumps may be formed on the second surface of each semiconductor chip.

The bumps may be connected with the first bonding pads of each semiconductor chip and may be formed on ends of the through electrodes disposed on the second surface of each semiconductor chip.

The connection members may include bonding wires.

In the semiconductor chip module, the bonding pads of each semiconductor chip may include first bonding pads disposed adjacent to one edge of the first surface and are connected with the first ends of the redistribution lines and second bonding pads disposed adjacent to another edge of the first surface opposite to the one edge. The bond fingers of the substrate may include first bond fingers disposed on portions of the first substrate surface, corresponding to the through electrodes of each semiconductor chip, and second bond fingers disposed on portions of the first substrate surface, corresponding to the second bonding pads of each semiconductor chip, and connected with the second bonding pads of each semiconductor chip by the connection members.

The semiconductor chip module may be placed over the first substrate surface of the substrate such that the first surface of each semiconductor chip faces the first substrate surface of the substrate.

The planar stack package may further include bumps formed to connect the second bonding pads of each semiconductor chip with the second bonding pads of the substrate.

The connection members may include bumps.

The through electrodes may be formed to pass through the second ends of the redistribution lines and the scribe lane.

### BRIEF DESCRIPTION OF THE DRAWINGS

FIG. 1 is a plan view illustrating a semiconductor chip module in accordance with an embodiment of the present invention.

FIG. 2 is a cross-sectional view taken along the line II-II′ of FIG. 1.

FIG. 3 is a plan view illustrating a semiconductor chip module in accordance with another embodiment of the present invention.

FIG. 4 is a cross-sectional view illustrating a planar stack package in accordance with another embodiment of the present invention.

FIGS. 5A to 5D are views explaining a method for manufacturing a planar stack package in accordance with another embodiment of the present invention.

FIG. 6 is a cross-sectional view illustrating a planar stack package in accordance with another embodiment of the present invention.

### DESCRIPTION OF SPECIFIC EMBODIMENTS

In various embodiments of the present invention, a semiconductor chip module is constructed by sawing at least two semiconductor chips completely manufactured at a wafer level, and a planar stack package is realized by applying the semiconductor chip module constructed in this way.

Accordingly, various embodiments of the present invention can increase capacity even with the same chip size. In particular, it is possible to overcome a limitation in ball pitch, and since semiconductor chips and a substrate are electrically connected using the space of a scribe lane, processability and reliability can be secured.

Hereafter, specific embodiments of the present invention will be described in detail with reference to the accompanying drawings.

It is to be understood herein that the drawings are not necessarily to scale and in some instances proportions may have been exaggerated in order to more clearly depict certain features of the invention.

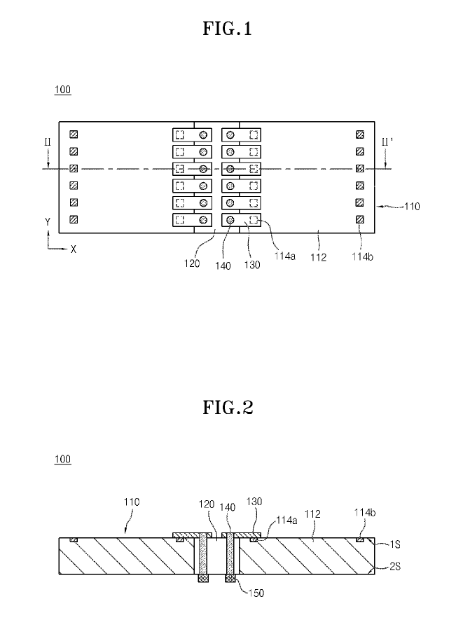

FIG. 1 is a plan view illustrating a semiconductor chip module in accordance with an embodiment of the present invention, and FIG. 2 is a cross-sectional view taken along the line II-II′ of FIG. 1.

Referring to FIGS. 1 and 2, a semiconductor chip module 100 includes a chip unit 110, redistribution lines 130 formed on respective semiconductor chips 112 of the chip unit 110, and through electrodes 140.

The chip unit 110 includes at least two semiconductor chips 112 disposed on the same plane. Each semiconductor chip 112 of the chip unit 110 has a first surface 1S and a second surface 2S that faces away from the first surface 1S. Also, each semiconductor chip 112 has a plurality of bonding pads 114a and 114b disposed on the first surface 1S. While not shown, each semiconductor chip 112 has a circuit unit formed therein that includes a data storage section and a data driving section.

The respective semiconductor chips 112 are edge pad type chips in which the bonding pads 114a and 114b are disposed adjacent to at least one edge of the first surface 1S. While not shown, the respective semiconductor chips 112 may be center pad type chips in which the bonding pads 114a and 114b are disposed on the center portion of the first surface 1S.

In the present embodiment, the chip unit 110 is defined through sawing in such a manner that two semiconductor chips 112 are arranged with a scribe lane 120 interposed in between. While not shown, the chip unit 110 may be defined through sawing in such a manner that three or more semiconductor chips 112 are arranged in a row with a scribe lane 120 interposed in between two adjacent semiconductor chips 112.

The redistribution lines 130 are formed on the first surface 1S of each semiconductor chip 112. Each redistribution line 130 has a first end and a second end. The first ends are connected to corresponding first bonding pads 114a, and the second ends are disposed over the scribe lane 120. In an embodiment of the invention, the redistribution lines 130 are formed to contact the first bonding pads 114a and the through electrodes 140 in portions of the scribe lane 120 near the first bonding pads 114a.

The through electrodes 140 are formed to pass through the scribe lane 120. In detail, the through electrodes 140 are formed to pass through the second ends of corresponding redistribution lines 130 and underlying portions of the scribe lane 120. The through electrodes 140 include a conductive layer which is filled in through holes. For example, the conductive layer may include a metal layer such as a copper layer, a tungsten layer, or an aluminum layer. In this case, the metal layer may further include a diffusion barrier such as Ti/TiN. The metal layer may be formed, for example, through a plating process or a deposition process.

The semiconductor chip module 100 in accordance with an embodiment of the present invention may further include bumps formed on the ends of the through electrodes 140, where the bumps are disposed on the second surface 2S of the semiconductor chip 112. The bumps 150 are formed for mounting the semiconductor chip module 100 when manufacturing a semiconductor package, and may include, for example, solder bumps and stud bumps.

In the semiconductor chip module 100 in accordance with an embodiment of the present invention, the chip unit 110 may be defined through sawing in such a manner that at least two semiconductor chips 112 are arranged in a row with a scribe lane 120 in between. At least two rows of these semiconductor chips may be arranged with a scribe lane interposed in between adjacent chips to form a N×N matrix or a M×N matrix of semiconductor chips. Matrices other than a regular N×N or M×N formation may be formed.

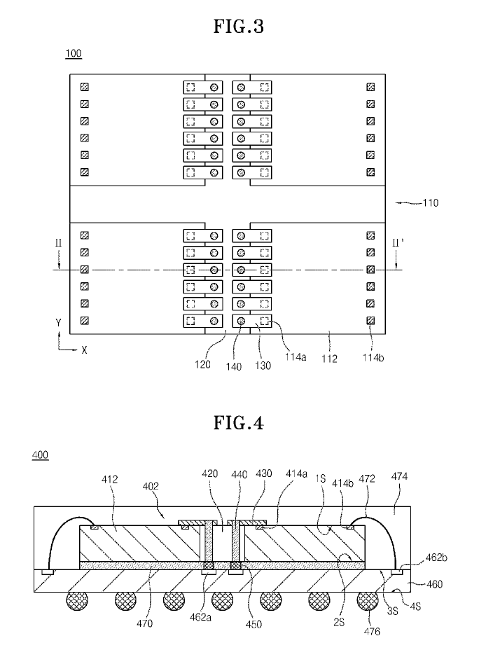

In detail, FIG. 3 is a plan view illustrating a semiconductor chip module in accordance with another embodiment of the present invention. The construction of the present embodiment is the same as that of the aforementioned embodiment except that only the number and arrangement of semiconductor chips are different. Therefore, repeated descriptions for the same components will be omitted herein, and only differences will be described in detail.

Referring to FIG. 3, a chip unit 110 may be defined through sawing in such a manner that at least two semiconductor chips 112 are arranged with a scribe lane 120 interposed in an X direction perpendicular to a Y direction along which bonding pads 114a and 114b are disposed. At least two rows of these semiconductor chips 112 are arranged with a scribe lane 120 interposed in the Y direction along which the bonding pads 114a and 114b are disposed. Accordingly, the chip unit 110 may comprise semiconductor chips 112 in a 2×2 matrix. In other words, in the conventional art, chips are sawed one by one in a sawing process performed for a wafer having completely undergone semiconductor manufacturing processes. However, in the present embodiment, unlike the conventional art, the chip unit 110 is defined by sawing a wafer by the unit of four semiconductor chips 112 in a 2×2 matrix with the scribe lanes 120 interposed between the semiconductor chips 112.

FIG. 4 is a cross-sectional view illustrating a planar stack package in accordance with another embodiment of the present invention, which is realized by applying the semiconductor chip module as described above.

Referring to FIG. 4, a planar stack package 400 includes a semiconductor chip module 402, a substrate 460, connection members 472, an encapsulation member 474, and coupling members 476.

The substrate 460 may be, for example, a printed circuit board. The substrate 460 has a first surface 3S and a second surface 4S that faces away from the first surface 3S, and includes a plurality of bond fingers 462a and 462b disposed on the first surface 3S and a plurality of ball lands (not shown) disposed on the second surface 4S. Also, the substrate 460 includes via patterns (not shown) formed in such a way as to connect the bond fingers 462a and 462b with corresponding ball lands. The bond fingers 462a and 462b include first bond fingers 462a disposed on portions of the first surface 3S serving as the upper surface of the substrate 460, corresponding to through electrodes 440 of the semiconductor chip module 402, and second bond fingers 462b disposed on portions of the first surface 3S of the substrate 460 defined outside the semiconductor chip module 402.

The semiconductor chip module 402 is disposed over the first surface 3S of the substrate 460. For example, the semiconductor chip module 402 is attached to the first surface 3S of the substrate 460 by an adhesive member 470 such as an adhesive film or an adhesive tape in such a manner that a second surface 2S of each semiconductor chip 412 faces the first surface 3S of the substrate 460.

As mentioned above, the semiconductor chip module 402 has a structure in which at least two semiconductor chips 412 are arranged with a scribe lane 420 interposed in between. Each semiconductor chip 412 of the semiconductor chip module 402 has a first surface 1S and the second surface 2S that faces away from the first surface 1S, and includes a plurality of bonding pads 414a and 414b disposed on the first surface 1S.

The semiconductor chip module 402 includes redistribution lines 430 connected with the first bonding pads 414a of each semiconductor chip 412. Each redistribution line 430 has a first end and a second end. The first ends are connected to corresponding first bonding pads 414a, and the second ends are disposed on the scribe lane 420.

The semiconductor chip module 402 includes the through electrodes 440 formed through the scribe lane 420. The through electrodes 440 are formed to pass through the scribe lane 420. In detail, the through electrodes 440 are formed to pass through the second ends of corresponding redistribution lines 430 and underlying portions of the scribe lane 420.

The bonding pads 414a and 414b of each semiconductor chip 412 are electrically connected with corresponding bond fingers 462a and 462b of the substrate 460. In detail, the first bonding pads 414a of each semiconductor chip 412, connected with the through electrodes 440, are electrically connected with the first bond fingers 462a disposed on the center portion of the first surface 3S of the substrate 460, by bumps 450. The second bonding pads 414b of each semiconductor chip 412 are electrically connected with the second bond fingers 462b disposed on the first surface 3S of the substrate 460 outside the semiconductor chip module 402, by the connection members 472 such as bonding wires. A patterned film may be used as the connection members 472 in place of bonding wires.

The encapsulation member 474 includes, for example, an EMC (epoxy molding compound). The encapsulation member 474 seals the first surface 3S of the substrate 460 including the semiconductor chip module 402 and the connection members 472 to protect the respective semiconductor chips 412 of the semiconductor chip module 402 from external influences.

The coupling members 476 include, for example, solder balls, and are attached to the ball lands disposed on the second surface 4S of the substrate 460, and may be used to mount the planar stack package 400 to an outside circuit.

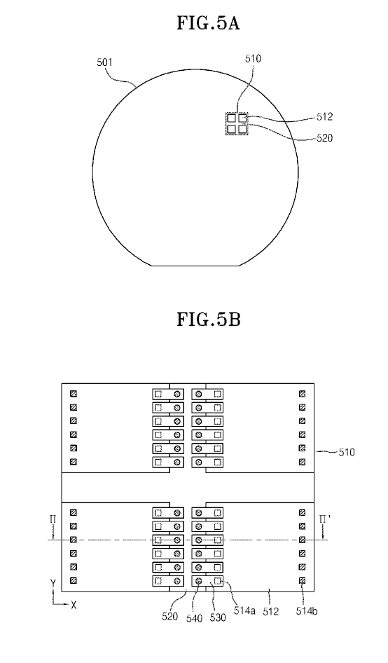

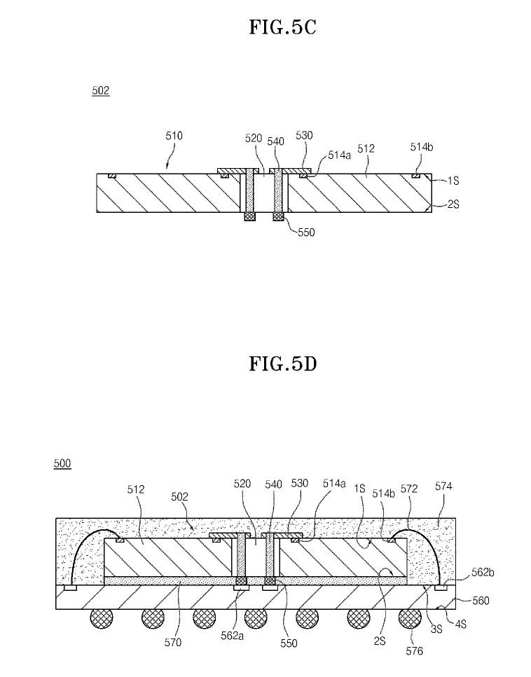

Hereafter, a method for manufacturing a planar stack package in accordance with another embodiment of the present invention will be briefly described with reference to FIGS. 5A to 5D.

Referring to FIG. 5A, at least two semiconductor chips 512, preferably, four semiconductor chips 512 are sawed as one chip unit 510 from a wafer 501 having completely undergone semiconductor manufacturing processes known in the art. Each chip unit 510 has a structure in which semiconductor chips 512 are arranged with a scribe lane 120 interposed in between.

Referring to FIG. 5B, redistribution lines 530 are formed on edge portions of the respective semiconductor chips 512 and adjacent portions of the scribe lane 520 through a redistribution process. Each redistribution line 530 is formed in such a manner that first ends are connected with first bonding pads 514a of the semiconductor chips 512 and the second ends extend onto the scribe lane 520.

Referring to FIG. 5C, through holes are formed to pass through the scribe lane 520 using a drilling process or an etching process. Preferably, the respective through holes are defined to pass through the second ends of the redistribution lines 530 and underlying portions of the scribe lane 520. Then, by filling a conductive layer, for example a metal layer such as a copper layer, a tungsten layer, or an aluminum layer, in the respective through holes through a plating process or a deposition process, through electrodes 540 are formed. Next, bumps 550 used for mounting in the manufacture of a package are formed on ends of the through electrodes 540 disposed on the second surfaces 2S of the semiconductor chips 512. As a result, a semiconductor chip module 502 may be manufactured with at least two semiconductor chips 512.

Referring to FIG. 5D, a substrate 560 is prepared. The substrate 560 has a first surface 3S and a second surface 4S that faces away from the first surface 3S, and includes a plurality of bond fingers 562a and 562b disposed on the first surface 3S and a plurality of ball lands (not shown) disposed on the second surface 4S. The semiconductor chip module 502 is attached to the first surface 3S of the substrate 560 by the medium of an adhesive member 570. At this time, the bumps 550 of the semiconductor chip module 502 are electrically connected with first bond fingers 562a disposed on the center portion of the first surface 3S of the substrate 560.

After that, second bonding pads 514b of the respective semiconductor chips 512 and second bond fingers 562b disposed on the first surface 3S of the substrate 560 outside the semiconductor chip module 502 are electrically connected with each other using connection members 572 such as bonding wires. Then, an encapsulation member 574 is formed to cover the first surface 3S of the substrate 560 including the semiconductor chip module 502 and the connection members 572. The encapsulation member 574 includes, for example, an EMC.

In succession, coupling members 576, such as solders balls, may be used as mounting means to an outside circuit and respectively attached to the respective ball lands disposed on the second surface 4S of the substrate 560. As a result, a planar stack package 500 is completely manufactured in accordance with an embodiment of the present invention.

The planar stack package and the method for manufacturing the same in accordance with various embodiments of the present invention provide several advantages. First, since at least two semiconductor chips are mounted in one package, large capacity can be secured. Second, processing is simplified when compared to the case of stacking single chips. Third, because at least two chips are handled as one chip unit under a situation where a chip size gradually decreases, limitations in processing may be overcome. Fourth, the electrical characteristics of chips may be improved.

Therefore, various embodiments of the present invention can improve the processability of a package manufacturing process and the reliability of a completely manufactured package.

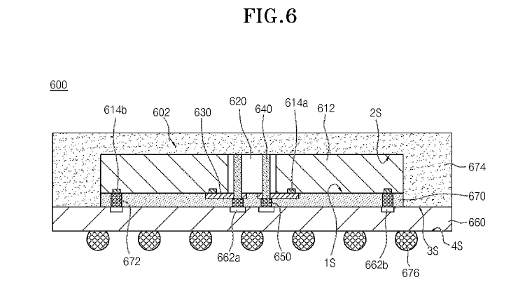

FIG. 6 is a cross-sectional view illustrating a planar stack package in accordance with another embodiment of the present invention. The planar stack package in accordance with the present embodiment is the same as the planar stack package in accordance with the aforementioned embodiment except that a semiconductor chip module is mounted in a flip chip type.

Referring to FIG. 6, a planar stack package 600 includes a semiconductor chip module 602, a substrate 660, connection members 672, an encapsulation member 674, and coupling members 676.

Similar to the aforementioned embodiment, the substrate 660 has a first surface 3S and a second surface 4S, and includes a plurality of bond fingers 662a and 662b disposed on the first surface 3S and a plurality of ball lands (not shown) disposed on the second surface 4S. The bond fingers 662a and 662b include first bond fingers 662a disposed on portions of the first surface 3S of the substrate 660, corresponding to through electrodes 640 of the semiconductor chip module 602, and second bond fingers 662b disposed on portions of the second surface 3S of the substrate 660, corresponding to second bonding pads 614b of the semiconductor chip module 602.

The semiconductor chip module 602 includes at least two semiconductor chips 612 with a scribe lane 620 interposed in between. Each semiconductor chip 612 has a first surface 1S and a second surface 2S that faces away from the first surface 1S, and includes a plurality of bonding pads 614a and 614b disposed on the first surface 1S. The bonding pads 614a and 614b are disposed adjacent to at least one edge of each semiconductor chip 612.

The semiconductor chip module 602 includes redistribution lines 630 disposed on edge portions of the respective semiconductor chips 612 and adjacent portions of the scribe lane 620. Each redistribution line 630 has a first end and a second end. The first ends are connected to corresponding first bonding pads 614a, and the second ends are disposed on the adjacent portions of the scribe lane 620.

The semiconductor chip module 602 includes the through electrodes 640 formed to pass through the second ends of the redistribution lines 630 and underlying portions of the scribe lane 620.

The semiconductor chip module 602 is flip-chip bonded to the first surface 3S of the substrate 660 in such a manner that the first surfaces 1S of the semiconductor chips 612 including the redistribution lines 630 face the first surface 3S of the substrate 660. The first bonding pads 614a of the semiconductor chips 612 and the first bond fingers 662a of the substrate 660 are electrically connected with each other by bumps 650, and the second bonding pads 614b of the semiconductor chips 612 and the second bond fingers 662b of the substrate 660 are electrically connected with each other by the connection members 672 such as bumps. Other conductive materials may be used as the connection members 672 in place of the bumps.

The space between the semiconductor chip module 602 and the substrate 660 is filled with an adhesive member 670. The adhesive member 670 performs an adhesion function between the semiconductor chip module 602 and the substrate 660 and an underfill function of filling the space between the semiconductor chip module 602 and the substrate 660. An insulation material other than an adhesive material may be used as the adhesive member 670.

The encapsulation member 674 includes, for example, an EMC, and seals the first surface 3S of the substrate 660 including the semiconductor chip module 602 to protect the respective semiconductor chips 612 of the semiconductor chip module 602 from external influences.

The coupling members 676 include, for example, solder balls, and are attached to the respective ball lands disposed on the second surface 4S of the substrate 660, for mounting the planar stack package 600 to an outside circuit.

The planar stack package according to the present embodiment of the invention provides advantages in that a manufacturing process is simplified when compared to the case of stacking single chips, and, because at least two chips are handled as one chip unit under a situation where a chip size gradually decreases, limitations in processing may be overcome.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor chip module comprising:
a chip unit including at least two semiconductor chips disposed with a scribe lane between adjacent semiconductor chips, and each of which has a first surface on which bonding pads are disposed and a second surface that faces away from the first surface;
redistribution lines, formed on the first surface of each semiconductor chip, having first ends connected with the bonding pads of each semiconductor chip and second ends that extend to and are disposed on the scribe lane; and
through electrodes formed to pass through the scribe lane and electrically connected with the second ends of the redistribution lines.

2. The semiconductor chip module according to claim 1, wherein the chip unit has a structure in which the scribe lane is in a direction perpendicular to a direction along which the bonding pads are disposed.

3. The semiconductor chip module according to claim 1, wherein the chip unit has a structure in which at least two semiconductor chips are arranged with the scribe lane interposed therebetween in a direction perpendicular to a direction along which the bonding pads are disposed, and at least two rows of these semiconductor chips are arranged with the scribe lane interposed therebetween in the direction along which the bonding pads are disposed.

4. The semiconductor chip module according to claim 3, wherein the semiconductor chips are arranged in a 2×2 matrix.

5. The semiconductor chip module according to claim 1, wherein the through electrodes are formed to pass through the second ends of the redistribution lines and the scribe lane.

6. The semiconductor chip module according to claim 1, further comprising:
bumps formed on ends of the through electrodes disposed on the second surface of each semiconductor chip.

7. A planar stack package comprising:
a semiconductor chip module including a chip unit including at least two semiconductor chips with a scribe lane interposed therebetween, and each semiconductor chip has a first surface on which bonding pads are disposed and a second surface that faces away from the first surface, redistribution lines formed on the first surface of each semiconductor chip where first ends are connected with the bonding pads of each semiconductor chip and second ends that extend to and are disposed on the scribe lane, and through electrodes formed to pass through the scribe lane and electrically connected with the second ends of the redistribution lines;
a substrate having a first substrate surface on which the semiconductor chip module is placed and a plurality of bond fingers are disposed and a second substrate surface that faces away from the first substrate surface and on which a plurality of ball lands are disposed; and
connection members electrically connecting the bonding pads of the semiconductor chips with the bond fingers of the substrate.

8. The planar stack package according to claim 7, wherein the chip unit has a structure in which the scribe lane is in a direction perpendicular to a direction along which the bonding pads are disposed.

9. The planar stack package according to claim 7, wherein the chip unit has a structure in which at least two semiconductor chips are arranged with the scribe lane interposed therebetween in a direction perpendicular to a direction along which the bonding pads are disposed, and at least two rows of these semiconductor chips are arranged with the scribe lane interposed therebetween in the direction along which the bonding pads are disposed.

10. The planar stack package according to claim 9, wherein the semiconductor chips are arranged in a 2×2 matrix.

11. The planar stack package according to claim 7,
wherein, in the semiconductor chip module, the bonding pads of each semiconductor chip include first bonding pads disposed adjacent to one edge of the first surface and connected with the first ends of the redistribution lines and second bonding pads disposed adjacent to another edge of the first surface opposite to the one edge, and
wherein the bond fingers of the substrate include first bond fingers disposed on a center portion of the first substrate surface and second bond fingers disposed on portions of the first substrate surface outside the semiconductor chip module and connected with the second bonding pads of each semiconductor chip by the connection members.

12. The planar stack package according to claim 11, wherein the semiconductor chip module further includes bumps formed to connect the first bonding pads of each semiconductor chip with the first bond fingers of the substrate.

13. The planar stack package according to claim 12, wherein the semiconductor chip module is placed over the first substrate surface of the substrate such that the second surface of each semiconductor chip faces the first substrate surface of the substrate, and the bumps are formed on the second surface of each semiconductor chip.

14. The planar stack package according to claim 13, wherein the bumps are connected with the first bonding pads of each semiconductor chip and are formed on ends of the through electrodes disposed on the second surface of each semiconductor chip.

15. The planar stack package according to claim 11, wherein the connection members comprise bonding wires.

16. The planar stack package according to claim 7,
wherein, in the semiconductor chip module, the bonding pads of each semiconductor chip include first bonding pads disposed adjacent to one edge of the first surface and connected with the first ends of the redistribution lines and second bonding pads disposed adjacent to another edge of the first surface opposite to the one edge, and
wherein the bond fingers of the substrate include first bond fingers disposed on portions of the first substrate surface, corresponding to the through electrodes of each semiconductor chip, and second bond fingers disposed on portions of the first substrate surface, corresponding to the second bonding pads of each semiconductor chip, and connected with the second bonding pads of each semiconductor chip by the connection members.

17. The planar stack package according to claim 16, wherein the semiconductor chip module is placed over the first substrate surface of the substrate such that the first surface of each semiconductor chip faces the first substrate surface of the substrate.

18. The planar stack package according to claim 17, further comprising:
bumps formed to connect the second bonding pads of each semiconductor chip with the second bonding pads of the substrate.

19. The planar stack package according to claim 16, wherein the connection members comprise bumps.

20. The planar stack package according to claim 7, wherein the through electrodes are formed to pass through the second ends of the redistribution lines and the scribe lane.
